(19) United States
(12) Patent Application Publication
(10) Pub. No.: US 2018/0158715 A1
(43) Pub. Date: Jun. 7, 2018

(54) SUBSTRATE SUPPORTING PIN, SUBSTRATE SUPPORTING DEVICE AND SUBSTRATE ACCESS SYSTEM

(71) Applicants: BOE TECHNOLOGY GROUP CO., LTD., Beijing (CN); HEFEI BOE OPTOELECTRONICS TECHNOLOGY CO., LTD., Hefei, Anhui (CN)

(72) Inventors: Xiaojun WANG, Beijing (CN); Xu SHI, Beijing (CN); Zhilong XU, Beijing (CN); Dagang LIU, Beijing (CN); Dongqing LI, Beijing (CN); Jianfan XU, Beijing (CN)

(21) Appl. No.: 14/907,922

(22) PCT Filed: Sep. 16, 2015
(86) PCT No.: PCT/CN2015/089761

§ 371 Date: Jan. 27, 2016

(30) Foreign Application Priority Data
Mar. 17, 2015 (CN) 201510116984.4

(51) Int. Cl. H01L 21/687; H01L 21/683; H01L 21/68

(52) U.S. Cl. CPC H01L 21/68742; H01L 21/68; H01L 21/6875; H01L 21/6838

(57) ABSTRACT

The disclosure provides a substrate supporting pin, a substrate supporting device and a substrate access system. The substrate supporting pin is used to support a substrate and includes a rod body. A supporting end of the rod body is provided with a rotating member that is able to roll along a surface of the substrate. Compared to the prior art, the disclosure can reduce or eliminate the damage of the substrate.

### FIELD OF THE INVENTION

The disclosure relates to the field of the preparation of display device, and in particular to a substrate supporting pin, a substrate supporting device having the substrate supporting pin and a substrate access system including the substrate supporting device.

### BACKGROUND OF THE INVENTION

During the preparation of a display device, there is a need to access and convey a substrate. At this point, it is necessary to place the substrate onto a supporting platform (for example, a base platform or a conveying platform) of a supporting device. When the substrate is accessed, substrate supporting pins may raise the substrate through the supporting platform so that mechanical arms can access the substrate; when the substrate supporting pins get down, the substrate may fall onto the supporting platform. However, when substrate supporting pins are brought into contact with the substrate, the substrate supporting pins may be displaced with respect to the substrate. Since the substrate supporting pins in the prior art have relatively sharp tips (as shown in FIG. 1), the substrate is inclined to be scratched by the tip of the substrate supporting pin.

### SUMMARY OF THE INVENTION

Objectives of the disclosure is to provide a substrate supporting pin, a substrate supporting device and a substrate access system, to prevent the substrate supporting pin from damaging the substrate.

To achieve above objectives, the disclosure provides a substrate supporting pin for supporting a substrate, the substrate supporting pin including a rod body, wherein a supporting end of the rod body is provided with a rotating member that is able to roll along a surface of the substrate.

Preferably, the rotating member includes a rotating wheel which is rotatably fixed to the supporting end of the rod body, such that the substrate is able to rest on a circumferential surface of the rotating wheel.

Preferably, the rod body is provided with a connection rod across a central axis of the rotating wheel, and the rotating wheel is rotatable about the connection rod.

Preferably, the rotating member comprises a rolling ball which is provided at the supporting end of the rod body and on the top of which the substrate is able to be supported.

Preferably, a gas passage is formed inside the rod body, the rolling ball is mounted at an opening of the gas passage, and a limiting seat is provided on a sidewall of the gas passage to confine the rolling ball in place.

Preferably, the limiting seat comprises a first annular stopper at the opening of the gas passage and a second annular stopper under the first annular stopper, each of the first annular stopper and the second annular stopper has an inner diameter smaller than a diameter of the rolling ball, and the centre of the rolling ball is restricted between the first annular stopper and the second annular stopper such that a top portion of the rolling ball is protruded from the first annular stopper.

Accordingly, the disclosure also provides a substrate supporting device, including a supporting platform and a plurality of substrate supporting pins penetrating through the supporting platform in a width direction of the supporting platform, and the substrate supporting pins are aforesaid substrate supporting pins provided in the disclosure.

Preferably, in the case that the rotating member includes the rolling ball mounted at the opening of the gas passage, the substrate supporting device further comprises an air-pressure regulation mechanism, which includes:

a pump communicated with the gas passage to introduce gas to or suck gas from the gas passage, such that an absolute value of a difference between an air pressure inside the gas passage and an environmental atmospheric pressure becomes greater than or equal to a predefine value.

Preferably, the pump is an inflator pump, an inflation port of which is communicated with the gas passage to introduce gas to the gas passage.

Preferably, the pump is a suction pump, a suction port of which is communicated with the gas passage to suck gas from the gas passage.

Preferably, the substrate supporting device further comprises an alignment mechanism which is arranged around the supporting platform and which is configured to place the substrate on the substrate supporting pins to an appropriate predefined place at respective levels.

Preferably, the alignment mechanism includes a first positioning member unit at a first level and a second positioning member unit at a second level, a plurality of positioning members in the first positioning member unit surround the predefined place corresponding to the first level, and a plurality of positioning members in the second positioning member unit surround the predefined place corresponding to the second level;

when the supporting ends of the substrate supporting pins are at the first level, the plurality of positioning members in the first positioning member unit are able to move towards the predefined place corresponding to the first level, so as to clamp the substrate resting on the substrate supporting pins to the predefined place corresponding to the first level; and

when the supporting ends of the substrate supporting pins are at the second level, the plurality of positioning members in the second positioning member unit are able to move towards the predefined place corresponding to the second level, so as to clamp the substrate resting on the substrate supporting pins to the predefined place corresponding to the second level.

Accordingly, the disclosure provides a substrate access system, including mechanical arms and aforesaid substrate supporting device provided in the disclosure.

In the disclosure, the rod body supporting ends of the substrate supporting pins are provided with the rotating members. The rotating members can roll along the substrate surface when the substrate is displaced with respect to the supporting pins, thereby reducing or eliminating the surface scratch of the substrate. Moreover, when the rotating member is the rolling ball, the gas passage is formed inside the rod body. When the substrate is being aligned, the gas passage is communicated with the environmental atmosphere, such that the rolling ball is able to roll to facilitate moving the substrate while the relative displacement between the substrate and the substrate supporting pins may not scratch the substrate. When the alignment is completed, gas is introduced to or sucked from the gas passage by the gas regulation mechanism to increase the absolute value of the difference between the air pressure inside the gas passage and the environmental atmospheric pressure, in order to fix the rolling ball to keep the substrate immobile. Compared with the prior art, the disclosure can easily regulate the substrate to the predefined place while reducing or eliminating the damage of the substrate, such that the substrate access system can accurately access the substrate, lowering the cost of manufacturing.

### BRIEF DESCRIPTION OF THE DRAWINGS

Accompanying drawings are provided for further understanding of this disclosure and constituting a part of the specification. Hereinafter, these drawings are intended to explain the disclosure together with the following specific embodiments, but should not be considered as a limitation of the disclosure. In which:

FIG. 1 is a schematic diagram showing a structure of a substrate supporting pin in the prior art;

FIG. 2 is a schematic diagram showing a structure of a substrate supporting pin according to a first embodiment of the disclosure;

FIG. 3 is a schematic diagram showing a structure of a substrate supporting pin according to a second embodiment of the disclosure;

FIG. 4 is an enlarged schematic diagram showing part I in FIG. 3;

FIG. 5 is a schematic diagram showing an operating state of the substrate supporting device when the substrate supporting pins are descending; and

FIG. 6 is a schematic diagram showing an operating state of the substrate supporting device when the substrate supporting pins are ascending.

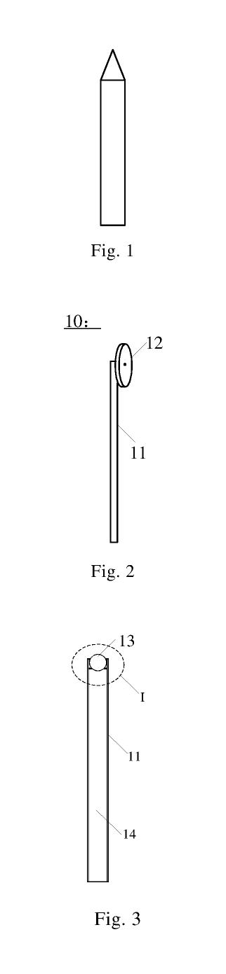

In reference numerals,
10—substrate supporting pin;
11—rod body;
12—rotating wheel;
13—rolling ball;
14—gas passage;
15—limiting seat;
15a—first annular stopper;
15b—second annular stopper;
20—supporting platform;
21—positioning member;
and 3—substrate.

### DETAILED DESCRIPTION OF THE EMBODIMENTS

Hereinafter, specific embodiments of the disclosure will be described in detail in conjunction with the accompanying drawings. It should be understood that the specific embodiments as set forth herein are merely for the purpose of illustration and explanation of the disclosure and should not be constructed as a limitation thereof.

As an aspect of the disclosure, there is provided a substrate supporting pin for supporting a substrate. As shown in FIGS. 2 and 3, the substrate supporting pin 10 may include a rod body 11. A supporting end of the rod body 11 is provided with a rotating member that is able to roll along a surface of the substrate.

When the substrate is displaced with respect to the substrate supporting pins 10 (for example, the substrate is aligned), the rotating member can roll along the surface of the substrate, such that a rolling friction is generated between the substrate and the substrate supporting pins, thereby reducing surface scratch of the substrate and improving quality of products.

As a specific embodiment of the disclosure, as shown in FIG. 2, the rotating member may include a rotating wheel 12 which is rotatably fixed to the supporting end of the rod body 11, such that the substrate is able to rest on a circumferential surface of the rotating wheel 12. The rotating wheel 12 can be regarded as a cylinder. When the substrate supporting pins uprightly stand to support the substrate, an end surface of the cylinder is perpendicular to the horizontal plane, and the vertex of the rotating wheel 12 is higher than the top of the rod body 10 such that the substrate can rest on the circumferential surface of the rotating wheel 12.

In particular, the rod body 11 can be provided with a connection rod (not shown in drawings) across a central axis of the rotating wheel 12, and the rotating wheel 12 can be rotatable about the connection rod. Since the rotating wheel 12 is in the shape of cylinder, when the rotating wheel 12 is fixed along its central axis, a rolling track of the rotating wheel 12 on the surface of the substrate is a straight line. In such an arrangement, when the substrate is displaced with respect to the substrate supporting pins 10, a displacement direction of the substrate is in conformity with a rolling direction of the rotating wheel 12 so that the surface of the substrate may not be scratched.

As a preferred embodiment of the disclosure, as shown in FIG. 3, the rotating member may comprise a rolling ball 13 which is provided at the supporting end of the rod body 11 and on the top of which the substrate can be supported. Since the rolling ball 13 can be rolled in any directions, when the substrate supported on the substrate supporting pins 10 is displaced to any direction, the rolling friction is generated between the substrate and each of substrate supporting pins 10, thereby reducing or eliminating the surface scratch of the substrate.

The arrangements of the rolling ball 13 are not limited in the disclosure. For example, a receptacle is formed at a tip of the supporting end of the rod body 11, in which the rolling ball 13 is mounted and rolled in any directions.

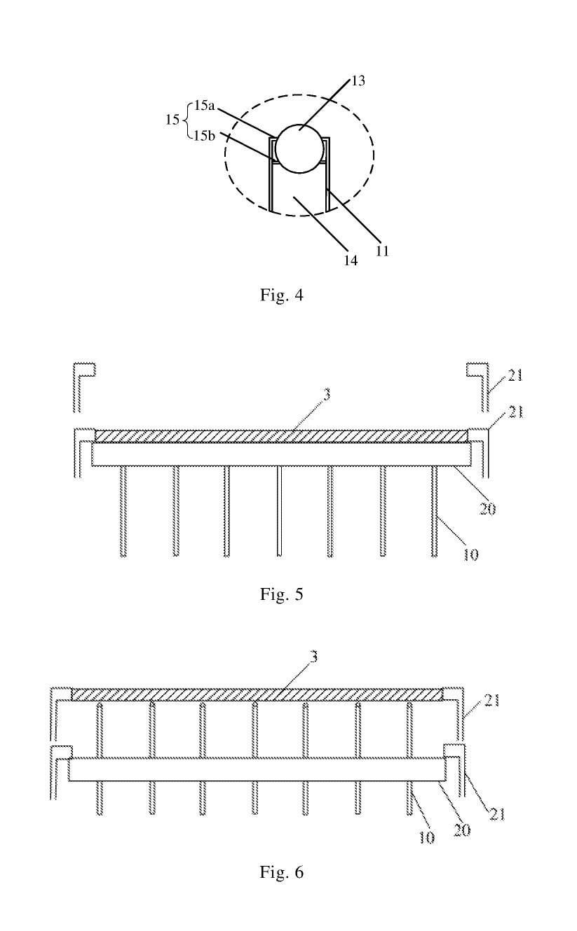

Preferably, as shown in FIGS. 3 and 4, a gas passage 14 is formed inside the rod body 11, the rolling ball 13 is mounted at an opening of the gas passage 14, and a limiting seat 15 is provided on a sidewall of the gas passage 14 to confine the rolling ball 13 in place to prevent the rolling ball 13 from escaping from the rod body without influence on the roll of the rolling ball 13.

In particular, as shown in FIG. 4, the limiting seat 15 may comprise a first annular stopper 15a at the opening of the gas passage 14 and a second annular stopper 15b under the first annular stopper 15a, each of the first annular stopper 15a and the second annular stopper 15b has an inner diameter smaller than a diameter of the rolling ball 13, and the centre of the rolling ball 13 is restricted between the first annular stopper 15a and the second annular stopper 15b such that a top portion of the rolling ball 13 is protruded from the first annular stopper 15a to support the substrate. Since each of the first annular stopper 15a and the second annular stopper 15b has the inner diameter smaller than the diameter of the rolling ball 13, the rolling ball 13 neither can escape upwards from the rod body nor drop downwards into the gas passage.

Of course, other structures can be adopted by the limiting seat 15 in the disclosure, as long as they are able to limit the position of the rolling ball 13 to prevent the rolling ball from moving upwards to escape from the rod body 11 or dropping downwards along the gas passage 14.

The terms “up” and “down” herein refer to up and down directions in FIGS. 3 and 4.

It could be understood, when an air pressure inside the gas passage 14 is higher than an environmental atmospheric pressure, the rolling ball 13 can be subjected to an upward push; and when the air pressure inside the gas passage 14 is lower than the environmental atmospheric pressure, the rolling ball can be subjected to a downward pressure. As an absolute value of a difference between the air pressure inside the gas passage 14 and the environmental atmospheric pressure increases, the push or the pressure force applied to the rolling ball 13 increases accordingly and in turn the friction force between the rolling ball 13 and the limiting seat 15 increases accordingly. When the difference between the air pressure inside the gas passage 14 and the environmental atmospheric pressure reaches a predefined value, the friction force between the rolling ball 13 and the limiting seat 15 becomes greater than a friction force between the rolling ball 13 and the substrate, such that the rolling ball 13 is kept immobile with respect to the rod body 11 (in other words, the rolling ball 13 cannot roll along the surface of the substrate) and thus the substrate can be prevented from a position offset when the substrate supporting pins rise and fall; when the absolute value of the difference between the air pressure inside the gas passage 14 and the environmental atmospheric pressure does not reach the predefined value, a small friction force is formed between the rolling ball 13 and the limiting seat 15, such that the rolling ball 13 is still able to roll to facilitate moving the substrate while the relative displacement between the substrate and the substrate supporting pins may not cause the surface scratch of the substrate.

Before the substrate supporting pins 10 raise the substrate, the substrate can rest at a predefined place. When the substrate supporting pins 10 ascend to push up the substrate to a predefined level, the substrate can be removed. If the substrate is displaced when the substrate supporting pins 10 ascend such that the projection of the substrate is deviated from the predefined place, the substrate can be aligned again. During the alignment, the gas passage 14 can be communicated with the environmental atmosphere, such that the rolling ball is able to roll along the substrate surface when the substrate is moved, thereby preventing the surface scratch of the substrate; upon the completion of the alignment, the air pressure inside the gas passage 14 is increased or decreased until the rolling ball 13 is immobile with respect to the rod body 11, thereby lowering the possibility of the movement of the substrate.

As another aspect of the disclosure, as shown in FIG. 5, there is provided a substrate supporting device including a supporting platform 20 and a plurality of substrate supporting pins 10 penetrating through the supporting platform 20 in a width direction of the supporting platform 20. The substrate supporting pins 10 are aforesaid substrate supporting pins 10 provided in the disclosure.

As described above, the gas passage 14 is formed inside the rod body 11, the rotating member includes the rolling ball 13 mounted at the opening of the gas passage 14, the limiting seat 15 is provided on the sidewall of the gas passage 14, the limiting seat 15 is configured to confine the rolling ball 13 in place to prevent the rolling ball from escaping from the rod body 11 or dropping downwards along the gas passage 14, and the substrate 3 can rest on the top of the rolling ball 13. When the absolute value of the difference between the air pressure inside the gas passage 14 and the environmental atmospheric pressure is greater than or equal to the predefined value, the push or the pressure force applied to the rolling ball 13 leads to a larger friction between the rolling ball 13 and the limiting seat 15 such that the rolling ball 13 is immobile and no long rolled with respect to the rod body 14.

In order to control the air pressure inside the gas passage 14, the substrate supporting device may further comprise an air-pressure regulation mechanism. The air-pressure regulation mechanism includes a pump communicated with the gas passage to introduce gas to or suck gas from the gas passage, such that the absolute value of the difference between the air pressure inside the gas passage 14 and the environmental atmospheric pressure becomes greater than or equal to the predefine value.

Preferably, the pump is an inflator pump, an inflation port of which is communicated with the gas passage to introduce gas to the gas passage. When the inflator pump introduces the gas into the gas passage 14, the air pressure inside the gas passage 14 is increased.

Preferably, the pump is a suction pump, a suction port of which is communicated with the gas passage to suck gas from the gas passage. When the suction pump sucks the gas from the gas passage 14, the air pressure inside the gas passage 14 is decreased.

In the embodiment, regardless of whether the inflator pump or the suction pump is adopted, the difference is generated between the air pressure inside the gas passage 14 and the environmental atmospheric pressure and the absolute value of the difference corresponds to an introduced gas volume or a sucked gas volume. In practical operation, the introduced gas volume or the sucked gas volume can be determined according to a volume V0 of the gas passage by an experimental method. For example, assuming that the environmental atmospheric pressure is P0 and the predefined value is P1, then the introduced gas volume into the gas passage would be (P0+P1)/P0−V0 or the sucked gas volume would be V0−(P0−P1)/P0.

In order to align the substrate 3, the substrate supporting device may further comprise an alignment mechanism which is arranged around the supporting platform 20 and which is configured to place the substrate 3 on the substrate supporting pins 10 to an appropriate predefined place at respective levels. As a result, when the substrate 3 rests on the supporting platform 20, the alignment mechanism can align the substrate 3; and when the substrate supporting pins 10 push up the substrate, the alignment mechanism can also align the substrate 3 to guarantee that the mechanical arms can exactly access the substrate. Herein, the predefined places of the substrate at various levels are only represented as different levels with the same orthographic projection.

In particular, as shown in FIGS. 5 and 6, the alignment mechanism may include a first positioning member unit at a first level and a second positioning member unit at a second level, a plurality of positioning members 21 in the first positioning member unit surround the predefined place corresponding to the first level, and a plurality of positioning members 21 in the second positioning member unit surround the predefined place corresponding to the second level.

When the supporting ends of the substrate supporting pins 10 are at the first level, the plurality of positioning members 21 in the first positioning member unit are able to move towards the predefined place corresponding to the first level, so as to clamp the substrate 3 resting on the substrate supporting pins 10 to the predefined place corresponding to the first level.

When the supporting ends of the substrate supporting pins 10 are at the second level, the plurality of positioning members 21 in the second positioning member unit are able to move towards the predefined place corresponding to the second level, so as to clamp the substrate 3 resting on the substrate supporting pins 10 to the predefined place corresponding to the second level.

The first level could be a level of supporting plane of the supporting platform 20, while the second level could be a predefined level when the mechanical arms access the substrate, as described above. The predefined place corresponding to the first level and the predefined place corresponding to the second level have the same projection on the horizontal plane. When the substrate is deviated from the predefined place, the positioning members surrounding the predefined place are moved towards the predefined place until positioning surfaces of the positioning members are aligned with a boundary of the predefined place, such that the substrate can be clamped in the appropriate predefined place.

In particular, the substrate supporting device may further comprise a driving mechanism which is connected to the substrate supporting pins and the alignment mechanism, respectively. The driving mechanism may comprise a position detector for detecting positions of the supporting ends of the substrate supporting pins 10. When the position detector detects that the supporting ends of the substrate supporting pins 10 are at the first level (in other words, the substrate is at the first level), the driving mechanism drives to move the positioning members in the first positioning unit to clamp the substrate in the predefined place corresponding to the first level; when the position detector detects that the supporting ends of the substrate supporting pins 10 are at the second level (in other words, the substrate is at the second level), the driving mechanism drives to move the positioning members in the second positioning unit to clamp the substrate in the predefined place corresponding to the second level.

As still another aspect of the disclosure, there is provided a substrate access system, including mechanical arms and above substrate supporting device provided in the disclosure. Since the rotating members of the substrate supporting pins are able to roll along the surface of the substrate to facilitate the positioning of the substrate, the accuracy with which the substrate access system accesses the substrate can be improved accordingly, thereby further reducing or eliminating the damage of the substrate.

It could be seen that the rod body supporting ends of the substrate supporting pins in the disclosure are provided with the rotating members. The rotating members can roll along the substrate surface when the substrate is displaced with respect to the supporting pins, thereby reducing or eliminating the surface scratch of the substrate. Moreover, when the rotating member is the rolling ball, the gas passage is formed inside the rod body. When the substrate is being aligned, the gas passage is communicated with the environmental atmosphere, such that the rolling ball is able to roll to facilitate moving the substrate while the relative displacement between the substrate and the substrate supporting pins may not scratch the substrate. When the alignment is completed, gas is introduced to or sucked from the gas passage by the gas regulation mechanism to increase the absolute value of the difference between the air pressure inside the gas passage and the environmental atmospheric pressure, in order to fix the rolling ball to keep the substrate immobile. Compared with the prior art, the disclosure can easily regulate the substrate to the predefined place, such that the substrate access system can accurately access the substrate while reducing or eliminating the damage of the substrate and lowering the cost of manufacturing.

It should be understood that the above implementations are merely exemplary embodiments for the purpose of illustrating the principle of the disclosure, and the disclosure is not limited thereto. Various modifications and improvements can be made by a person having ordinary skill in the art without departing from the spirit and essence of the disclosure. Accordingly, all of the modifications and improvements also fall into the protection scope of the disclosure.

1. A substrate supporting pin for supporting a substrate, the substrate supporting pin including a rod body, wherein
a supporting end of the rod body is provided with a rotating member that is able to roll along a surface of the substrate.

2. The substrate supporting pin according to claim 1, wherein
the rotating member includes a rotating wheel which is rotatably fixed to the supporting end of the rod body, such that the substrate is able to rest on a circumferential surface of the rotating wheel.

3. The substrate supporting pin according to claim 2, wherein
the rod body is provided with a connection rod across a central axis of the rotating wheel, and the rotating wheel is rotatable about the connection rod.

4. The substrate supporting pin according to claim 1, wherein
the rotating member comprises a rolling ball which is provided at the supporting end of the rod body and on the top of which the substrate is able to be supported.

5. The substrate supporting pin according to claim 4, wherein
a gas passage is formed inside the rod body, the rolling ball is mounted at an opening of the gas passage, and a limiting seat is provided on a sidewall of the gas passage to confine the rolling ball in place.

6. The substrate supporting pin according to claim 5, wherein
the limiting seat comprises a first annular stopper at the opening of the gas passage and a second annular stopper under the first annular stopper, each of the first annular stopper and the second annular stopper has an inner diameter smaller than a diameter of the rolling ball, and the centre of the rolling ball is restricted between the first annular stopper and the second annular stopper such that a top portion of the rolling ball is protruded from the first annular stopper.

7. A substrate supporting device, which includes a supporting platform and a plurality of substrate supporting pins penetrating through the supporting platform in a width direction of the supporting platform, wherein the substrate supporting pins are the substrate supporting pins according to claim 1.

8. The substrate supporting device according to claim 7, wherein
the substrate supporting device further comprises an alignment mechanism which is arranged around the supporting platform and which is configured to place the substrate on the substrate supporting pins to an appropriate predefined place at respective levels.

9. The substrate supporting device according to claim 8, wherein
the alignment mechanism includes a first positioning member unit at a first level and a second positioning member unit at a second level, a plurality of positioning members in the first positioning member unit surround the predefined place corresponding to the first level, and a plurality of positioning members in the second positioning member unit surround the predefined place corresponding to the second level;
when the supporting ends of the substrate supporting pins are at the first level, the plurality of positioning members in the first positioning member unit are able to move towards the predefined place corresponding to the first level, so as to clamp the substrate resting on the substrate supporting pins to the predefined place corresponding to the first level; and
when the supporting ends of the substrate supporting pins are at the second level, the plurality of positioning members in the second positioning member unit are able to move towards the predefined place corresponding to the second level, so as to clamp the substrate resting on the substrate supporting pins to the predefined place corresponding to the second level.

10. A substrate supporting device, which includes a supporting platform and a plurality of substrate supporting pins penetrating through the supporting platform in a width direction of the supporting platform, wherein the substrate supporting pins are the substrate supporting pins according to claim 4.

11. The substrate supporting device according to claim 10, wherein
the substrate supporting device further comprises an air-pressure regulation mechanism, which includes:
a pump communicated with the gas passage to introduce gas to or suck gas from the gas passage, such that an absolute value of a difference between an air pressure inside the gas passage and an environmental atmospheric pressure becomes greater than or equal to a predefine value.

12. The substrate supporting device according to claim 11, wherein
the pump is an inflator pump, an inflation port of which is communicated with the gas passage to introduce gas to the gas passage.

13. The substrate supporting device according to claim 11, wherein
the pump is a suction pump, a suction port of which is communicated with the gas passage to suck gas from the gas passage.

14. The substrate supporting device according to claim 10, wherein
the substrate supporting device further comprises an alignment mechanism which is arranged around the supporting platform and which is configured to place the substrate on the substrate supporting pins to an appropriate predefined place at respective levels.

15. The substrate supporting device according to claim 14, wherein
the alignment mechanism includes a first positioning member unit at a first level and a second positioning member unit at a second level, a plurality of positioning members in the first positioning member unit surround the predefined place corresponding to the first level, and a plurality of positioning members in the second positioning member unit surround the predefined place corresponding to the second level;
when the supporting ends of the substrate supporting pins are at the first level, the plurality of positioning members in the first positioning member unit are able to move towards the predefined place corresponding to the first level, so as to clamp the substrate resting on the substrate supporting pins to the predefined place corresponding to the first level; and
when the supporting ends of the substrate supporting pins are at the second level, the plurality of positioning members in the second positioning member unit are able to move towards the predefined place corresponding to the second level, so as to clamp the substrate resting on the substrate supporting pins to the predefined place corresponding to the second level.

16. A substrate access system, which includes mechanical arms and the substrate supporting device according to claim 7.

17. A substrate access system, which includes mechanical arms and the substrate supporting device according to claim 8.

18. A substrate access system, which includes mechanical arms and the substrate supporting device according to claim 9.

19. A substrate access system, which includes mechanical arms and the substrate supporting device according to claim 10.

20. A substrate access system, which includes mechanical arms and the substrate supporting device according to claim 11.
